(19) United States
(12) Patent Application Publication
(10) Pub. No.: US 2018/0373344 A1
(43) Pub. Date: Dec. 27, 2018

(54) DATA ENTRY KEYBOARD

(71) Applicant: Paul Streitz, Shelton, CT (US)

(72) Inventor: Paul Streitz, Shelton, CT (US)

(21) Appl. No.: 15/884,838

(22) Filed: Jan. 31, 2018

Related U.S. Application Data
(63) Continuation-in-part of application No. 13/691,960, filed on Dec. 3, 2012, now Pat. No. 9,933,857.

(51) Int. Cl. G06F 3/02; H01H 13/83; H03K 17/967; H03K 17/96

(52) U.S. Cl. CPC G06F 3/0219; H03K 17/96; H03K 17/967; H01H 13/83

(57) ABSTRACT

An apparatus for entering alphabetic data into a computer or other electronic or mechanical devices with a keyboard, wherein the keys are placed in an ordered arrangement. The vowels AEIOU are grouped together and arranged on a left side of the keyboard. The vowels are arranged in alphabetic order vertically across the three rows of keys with letters AE on the top row, the letters IO on the middle row, and the letter U on the bottom row. Each of the vowels has a same color. Consonants are arranged in consonant groups comprised of BCD, FGHJK, LMNPQ, RST, and VWXYZ. The consonant groups are arranged from left to right in alphabetic group order. The consonants in each of the consonant groups are arranged vertically across the three rows of the keys. The key groupings may also be differentiated by color.

This application is a continuation-in-part of commonly-owned U.S. patent application Ser. No. 13/691,960, filed on Dec. 3, 2012, which is incorporated herein and made a part hereof by reference.

### TECHNICAL FIELD

This invention relates generally to the field of keyboards and more specifically to an apparatus for entering alphabetic data into a computer or other electronic or mechanical devices.

### BACKGROUND

The term “keyboard” as used herein shall refer to all devices for inputting alphabetic letters, regardless whether the devices be mechanical or electric typewriters, personal computers, laptop computers, tablet computers, smart phones, smart pads, touch screens, or any other type of mechanical or electronic device used for the entry of data.

The invention of the typewriter is credited to C. Latham Sholes in 1867. Thereafter, Sholes designed the QWERTY keyboard to prevent typewriters from jamming. Sholes designed the QWERTY keyboard in about 1872. It was an unpatented universal design. Before this design each manufacturer had its own keyboard layout which made uniform learning of typing impossible. Sholes later filed for and was granted U.S. Pat. No. 558,428 (1896) for a typewriter, but the keyboard layout was not shown in the patent. FIG. 1 depicts the prior art Allen Keyboard, U.S. Pat. No. 185,714 (1876). The keyboard has five rows of letters. The English language vowels, plus the letter “Y” which occasionally has a vowel pronunciation of “e” in certain words such as “city,” are on the bottom row of the keyboard. The next row up started with B, C, and D. The consonant keys were arranged in alphabetical order from left to right, bottom to top row. The keys were arranged in diagonal columns to allow each key to throw a lever. This was apparently the last attempt to arrange the letters in an order that was systemized and intuitive to English speakers. This keyboard was easier to learn. It was intuitive because it separated the letters into easily recognizable groups that one learns when first encountering the alphabet. The twenty-six letters of the alphabet are typically learned in a standard alphabetic order A, B, C, D, etc. The distinction is then made between vowels and consonants with the vowels being learned in the same order as they appear in the total alphabet, A, E, I, O, U. However, this design had the limitation that the keys were in five rows, requiring a long keystroke to the top letters of the keyboard.

The success of the Remington Standard No. 2 typewriter in 1878, which used the QWERTY keyboard, led to the universal adoption of the QWERTY layout. FIG. 2 depicts the prior art QWERTY keyboard. The name of the keyboard is derived from the letters on the left hand side of the top row. The letters are arranged in a format that was designed to slow down the rate of typing on early mechanical typewriters, as the early mechanical systems could not keep up with the rate at which the keys were being struck. In such early systems, the operator could press keys in sequence faster than the machine could return the previous key to its starting position. With the QWERTY keyboard, the placement of the keys has no logical sequence relating to the order of letters in the English alphabet. There was no consideration given to the ease of learning the keyboard. It was an open design and is hailed as one of the successful examples of open standards for an industry

The QWERTY keyboard was designed to scatter the most commonly struck keys to slow down the speed of the operator. For instance, a frequently pressed vowel “a” is pressed by the small finger of the left hand, which is a weak finger and the mechanical typewriters of the time required a forceful stroke to bring the key up to strike the ribbon and make an impression. The QWERTY keyboard was laid out in three rows with 10 keys in the top row, 9 in the second row, and 7 in the third row, with the keys arranged in diagonal columns to allow the keys to depress a lever.

However, the QWERTY keyboard did have one significant design feature: efficiency. The design of the keyboard with three rows with 10 letters in the first row, 9 letters in the second row and 7 letters in the third row. This created a middle home row for the fingers to rest and then every key is then either in the home row, or one row up or one row down from the home row.

The QWERTY keyboard to a beginning typist is completely random and the position of each letter needs to be painfully memorized by repetition. It takes weeks if not months to train a typist to a high level of skill. Despite this significant limitation, the ubiquitous presence of the QWERTY keyboard on all typewriters made changing to an easier to learn system commercially unfeasible.

U.S. Pat. No. 560,572 (1896), shows a typewriter with the QWERTY keyboard layout. However, this patent does not make any claims to the arrangement of the letters on the keyboard layout. As mentioned above, the QWERTY keyboard layout was an open design and not patented. U.S. Pat. No. 943,466 (1909) offered a non-QWERTY keyboard, wherein the most commonly used letters of the alphabet were arranged in the center of the keyboard. This was apparently the first keyboard arrangement designed to increase typing speed that received a U.S. Patent.

Typists were regarded as high skill employees and typing speed and accuracy was considered a desirable feature of employees. Subsequently, there was a search for a faster keyboard. August Dvorak was granted U.S. Pat. No. 2,040,248 (1936) for a new keyboard. FIG. 3 depicts the prior art Dvorak keyboard, wherein the arrangement of the letters is designed to shorten the length of stroke of the most frequently used letters in the English language, in order to increase typing speed. The placement of the keys has no logical sequence relating to the order of letters in the English alphabet. The Dvorak keyboard was designed for maximum speed by carefully measuring the distance the operator had to reach to type each letter. Ease of learning the keyboard was not considered. Again, to a beginning typist the Dvorak keyboard was a random arrangement of letters and the finger used to type each letter had to be learned by rote and extensive practice. The Dvorak keyboard layout comprised, from top to bottom, 7, 10 and 9 letter keys in each of three rows. This differentiated it from the QWERTY design of three rows of 10, 9, and 7 letter keys. The Dvorak keyboard never made significant headway for typewriters because the marginal difference in speed was more than negated by the long period of training necessary to change from one random arrangement of letters to another random arrangement of letters.

Starting in the 1970's with the introduction of the personal computer, the typing keyboard was separated from the physical computer. The QWERTY keyboard arrangement was adopted by manufacturers for the computer keyboards. Once again, the slight advantage in speed provided by the Dvorak keyboard did not make up for the long learning time. The Dvorak keyboard remains available for computers but only occupies an insignificant share of the market.

Thus, the main keyboard layouts had as their central concern the speed of the typist and developed their systems in response to this concern, but they had opposite goals. The intention of the QWERTY system was to slow down typing speed while the Dvorak system was to speed up typing. The Dvorak and QWERTY designers never paid any consideration to the difficulty of learning the keyboard layout. To a new learner of a keyboard layout, both the QWERTY and Dvorak systems appear as random arrangements that must be painstakingly learned through repetition.

Other keyboard layouts have been proposed using a three row arrangement of letters, for example: U.S. Pat. Nos. 943,466 (1909), 1,336,122 (1920), 1,342,244 (1920), 1,506,426 (1924), 2,080,457 (1937), 4,519,721 (1985), 4,613,247 (1986), 5,352,050 (1994), 5,498,088 (1996), 5,836,705 (1998), 5,879,089 (1999), 6,830,396 (2004), 6,965,372 (2005), 7,008,127 (2006), and 7,104,711 (2006). These keyboards presented a typist with an apparently random arrangement of letters because the purpose of the arrangement was typing speed with no consideration given to ease of use or speed of learning. U.S. Pat. No. Patent no. 4,927,279 (1990) separates some of the vowels from the consonants and arranges the letters in alphabetical order. This patent has a plurality of keyboard designs some of which order the vowels separately from the consonants and discloses different configurations of letter keys in a three row design. The purpose of these arrangements is speed, not ease of learning.

A foreign patent has a colored keyboard with a QWERTY keyboard design, AU patent no. 2012100915 (2012). This patent gives colors to the letters based on their proximity to the center of the keyboard or to designate a specific row. The patent does not require color coding, but suggests keys could be color coded to help the typist. The patent then discloses alternative color schemes.

In a study of computer users, the average typing rate was thirty-three words per minute to transcribe a document and the rate for composition was nineteen words per minute. This indicates that the overwhelming majority of computer users are not typing at any great rate of speed. Therefore, improving anyone's rate of typing from sixty-five to seventy words per minute for a skilled typist by having the typist learn a completely new keyboard arrangement is not a worthwhile endeavor that offsets the disability in quickly learning the keyboard. In contrast, providing a keyboard that is easier to learn and easier to use would provide a significant savings in learning times for beginning typists and aid slow typists.

Numerous keyboard layouts have been proposed that are physically different from the three row arrangement of the QWERTY keyboard. Along with the different arrangement of the physical keyboard is a different arrangement of the letters. The first of these was U.S. Pat. No. 1,260,543 (1918) which employed some eighty-one keys of various combinations of numbers and letters. This was followed by U.S. Pat. No. 1,292,319 (1920) which employed keys arranged in alphabetical order over five rows of keys. Each of these keyboards was designed to maximize speed of typing and did not consider ease of learning. Subsequently, a large number of designs have been patented that are different from the three-row 10-9-7 sequence of alphabetic keys. However, none of these designs appear to be more efficient than the three row design of the QWERTY keyboard.

Over the decades typing has changed from a skilled trade of secretarial work to a mass skill such as driving a car. Today, children in grade school learn keyboarding skills in the seventh grade, if not earlier. The mass use of cell phones and computers has made using a keyboard almost universal for all professions. Thus, the QWERTY keyboard system's random arrangement of letters now presents an even greater barrier and considerable waste of time, effort and money spent learning a keyboard layout designed for a mechanical keyboard of the 1900's.

Based on the above, there exists a need in the art for a keyboard arrangement of letters that enable the beginning learner and any user to quickly and efficiently identify the position of each of the letters on the keyboard. In order to accomplish this, the letters must be arranged in a manner that takes into account the learned knowledge of the user, that is, the learned order of the alphabetic sequence of letters and the distinction between the vowels and the consonants.

### SUMMARY OF THE INVENTION

The primary object of the present invention is to provide a computer keyboard that is easier to learn.

Another object of the present invention is to provide a computer keyboard that is laid out in an intuitive manner familiar to any reader of the English language.

Another object of the present invention is to provide a computer keyboard wherein the alphabetic letters are placed in an ordered arrangement that is consistent with the sequence of the Roman alphabet that begins with the letter A and ends with the letter Z, reading left to right.

Other objects and advantages of the present invention will become apparent from the following descriptions, taken in connection with the accompanying drawings, wherein, by way of illustration and example, example embodiments of the present invention are disclosed.

In accordance with an example embodiment of the present invention, there is disclosed an apparatus for entering alphabetic data into a computer or other electronic or mechanical devices, comprising: a keyboard wherein the alphabet letters are placed in an ordered arrangement of keys on a three alphabetic row keyboard of 10-9-7 keys per row. The keys may be grouped together to form seven groups of keys. The vowels are grouped together and arranged on the left side of the keyboard arranged in alphabetical order, left to right, top to bottom in three rows. The letters AE are arranged on the top row, the letters IO are arranged on the middle row, and the letter U is arranged on the bottom row. Each vowel may have the same color code. The consonants may be arranged in groups. The consonant groups may be arranged from left to right in alphabetic group order. The consonants within the consonant groups (with the exception of the JK group) may be arranged vertically across the three rows of the keyboard, and the consonants in each group has a color code. The letters JK may be arranged horizontally on the bottom row.

In a further example embodiment of the present invention, the keys may be divided into six groups of keys. The keys are placed in an ordered arrangement with the vowels AEIOU grouped together and arranged on a left side of the keyboard. The vowels are arranged in alphabetic order vertically across the three rows of keys with letters AE on the top row, the letters IO on the middle row, and the letter U on the bottom row. Each of the vowels may have a same color. The consonants may be arranged in consonant groups comprised of the letters BCD, FGHJK, LMNPQ, RST, and VWXYZ. The consonant groups may be arranged from left to right in alphabetic group order. The consonants in each of the consonant groups may be arranged vertically across the three rows of the keys.

The vowels and the consonants may be colored in order to differentiate the key groupings, with adjacent groups being differently colored. For example, all of the consonants within both of the consonant groups BCD and RST may be of a same first color which is a different color than any other of the consonant groups and the vowels. Each of the consonants within the consonant group FGHJK may be of a same second color. Each of the consonants within the consonant group LMNPQ may be of a same third color. Each of the consonants within the consonant group VWXYZ may be of a same fourth color. The first color, the second color, the third color, and the fourth color may each comprise different colors.

The letters B, C, and D may be arranged on the top, middle, and bottom rows, respectively. The letters F and G may be arranged on the top row, the letter H may be arranged on the middle row, and the letters JK may be arranged on the bottom row. The letters L and M may be arranged on the top row, the letters N and P may be arranged on the middle row, and the letter Q may be arranged on the bottom row. The letters R, S, and T may be arranged on the top, middle, and bottom rows, respectively. The letters V and W may be arranged on the top row, the letters X and Y may be arranged on the middle row, and the letter Z may be arranged on the bottom row.

In any of the example embodiments, with the keys or the lettering on the keys may be colored. For example, the letters may be colored letters on a black background. Alternatively, the key itself (e.g., the background) may be colored with the letters appearing in black or white. In addition, the keys of each group may be one color with the lettering of each group in a contrasting color. Any combination of colored lettering and colored keys may be used, as long as adjacent groupings are differentiated by different colored keys and/or lettering.

Some of the groupings of keys may have the same color, as long as adjacent groups of keys are of a different color. For example, in one example embodiment, the vowels may be the same color as the each of the consonants within the consonant group VWXYZ.

The keyboard may comprise one of a mechanical keyboard, a computer keyboard, an electronic keyboard, a smartphone keyboard, a tablet keyboard, a touch screen keyboard, or the like.

The keyboard may comprise a dual character keyboard where the alphabetic keys comprise both an English language letter and a foreign language letter, character, and/or symbol. For example, the computer keyboard can be employed in dual character keyboards that also use written symbols such Chinese/Japanese/Arabic characters or other languages. The computer keyboard would also provide these users with a logical arrangement of the letters consistent with their learning of the English language.

### BRIEF DESCRIPTION OF THE DRAWINGS

The present invention will hereinafter be described in conjunction with the appended drawing figures, wherein like reference numerals denote like elements, and:

FIG. 1 shows the prior art layout of the Allen keyboard;

FIG. 2 shows the prior art layout of the QWERTY keyboard;

FIG. 3 shows the prior art layout of the Dvorak keyboard;

FIG. 4 shows a keyboard layout of keys in accordance with an example embodiment of the present invention;

FIG. 5 shows a keyboard layout of keys in accordance with a further example embodiment of the present invention; and

FIG. 6 shows a keyboard layout having dual character keys in accordance with a further example embodiment of the present invention.

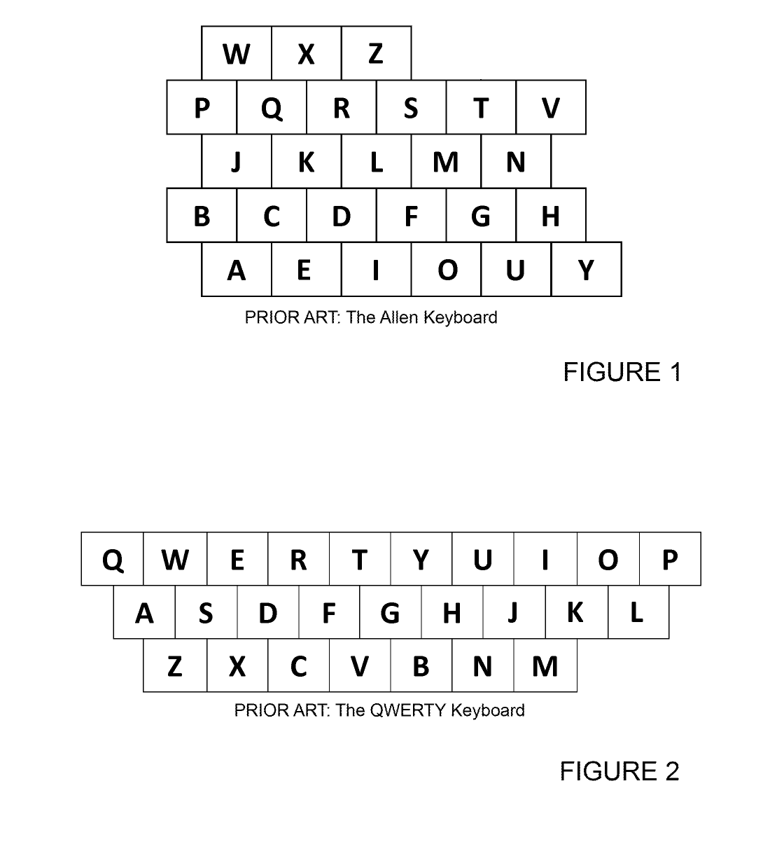

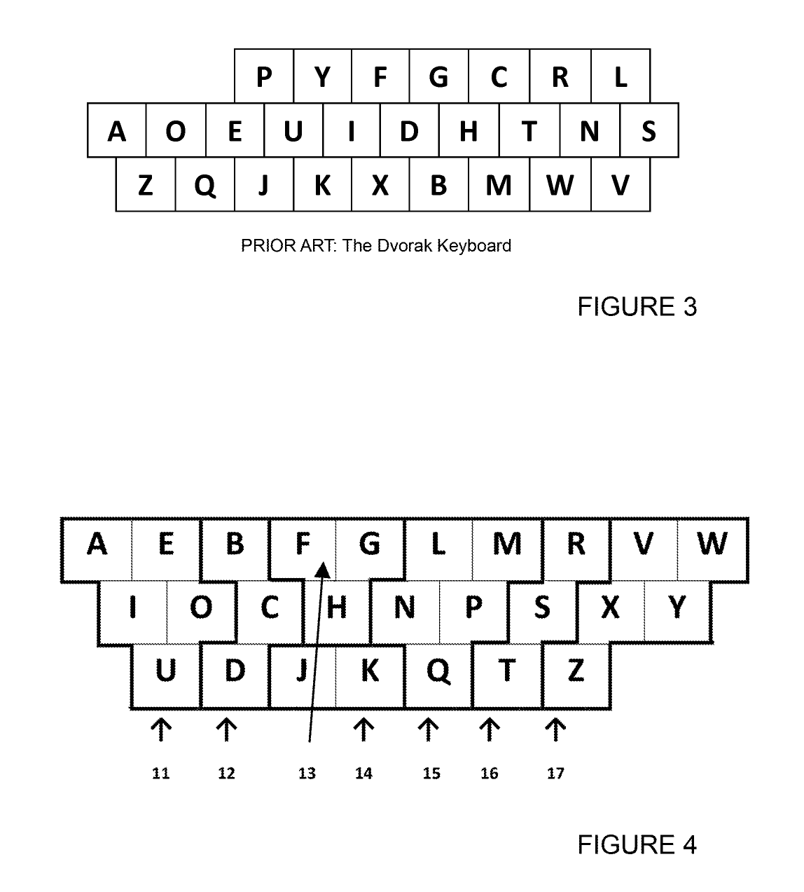

### DETAILED DESCRIPTION

The ensuing detailed description provides exemplary embodiments only, and is not intended to limit the scope, applicability, or configuration of the invention. Rather, the ensuing detailed description of the exemplary embodiments will provide those skilled in the art with an enabling description for implementing an embodiment of the invention. It should be understood that various changes may be made in the function and arrangement of elements without departing from the spirit and scope of the invention as set forth in the appended claims.

The present invention relates to an apparatus for entering alphabetic data into a computer or other electronic or mechanical devices comprised of a keyboard of three rows of 10-9-7 alphabetic keys, with ten keys on a top row, nine keys on a middle row and seven keys on a bottom row.

FIG. 4 depicts one example embodiment of a keyboard layout in accordance with the present invention. In the FIG. 4 example embodiment, the keys are divided into seven groups. The keys are placed in an ordered arrangement relating to the understanding and order of the letters in the English alphabet on a three row keyboard of 10-9-7 keys per row. The vowels Group AEIOU (11) are to the left on the keyboard and the vowels may each have the same color. The vowels may be arranged vertically across the three rows of keys with the letters AE on the top row, the letters IO on the middle row, and the letter U on the bottom row.

The consonants are arranged in alphabetical groups from left to right starting from the right of Group (11). The consonants within each group may all be of the same color. Group (12) consists of the consonants BCD. The group BCD may be arranged vertically across the three rows of keys, with the letter B on the top row, the letter C on the middle row, and the letter D on the bottom row. Group (13) consists of the consonants FGH. The letters FGH may be arranged vertically across two rows of keys. For example, the letters F and G may be arranged on the top row, and the letter H may be arranged on the middle row. Group (14) consists of the consonants JK. The consonants J and K may be arranged horizontally on the bottom row. Group (15) consists of the consonants LMNPQ. The letters LMNPQ may be arranged vertically across the three rows of keys, with the letters L and M on the top row, the letters N and P on the middle row, and the letter Q on the bottom row. Group (16) consists of the consonants RST. The group RST may be of the same color as the group BCD, or it may be of a different color. The letters RST may be arranged vertically across the three rows of keys, with the letter R on the top row, the letter S on the middle row, and the letter T on the bottom row. Group (17) consists of the consonants VWXYZ. The group VWXYZ may be arranged vertically across the three rows of keys, with the letters V and W on the top row, the letters X and Y on the middle row, and the letter Z on the bottom row.

Each consonant group of letters may have a different color, with the exception of Group (12) and Group (16) which may share the same color. The vowels may be of a different color than any of the consonant groups, or may be the same color as one or more of the consonant groups. For example, colors yellow, blue, red, and green may be used to differentiate the groups of keys from each other. Adjacent groups of keys should be differently colored. For example, the vowels may be yellow, and the adjacent group BCD may be red. The next group, FGH may be green. The JK group may be blue. The next group, RST, may be red. The last group, VWXYZ, may be yellow. Different color configurations may be provided for each group, and other colors may be used to differentiate the groups, such as tan, purple, gray, white, and the like.

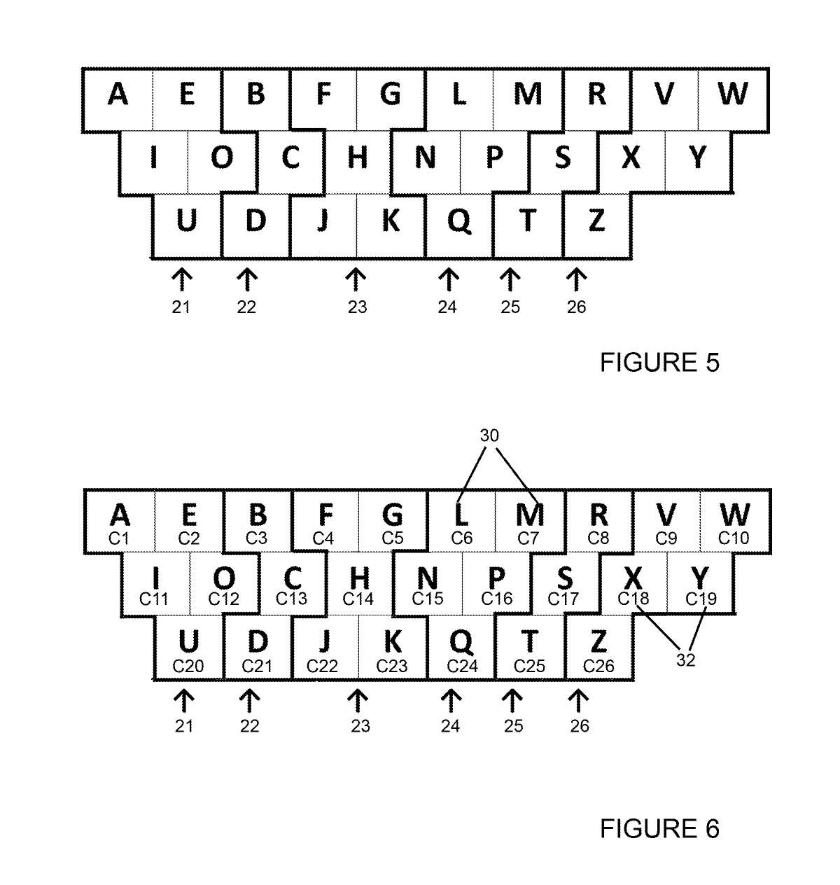

FIG. 5 shows a further example embodiment of a keyboard layout in accordance with the present invention. In the FIG. 5 example embodiment, the keys are divided into six groups. The keys are placed in an ordered arrangement with the vowels AEIOU grouped together and arranged on a left side of the keyboard. The vowels Group (21) are arranged in alphabetic order vertically across the three rows of keys with letters AE on the top row, the letters IO on the middle row, and the letter U on the bottom row. Each of the vowels may have a same color. The consonants may be arranged in consonant groups (22), (23), (24), (25), and (26) comprised of the letters BCD, FGHJK, LMNPQ, RST, and VWXYZ, respectively. The consonant groups may be arranged from left to right in alphabetic group order. The consonants in each of the consonant groups may be arranged vertically across the three rows of the keys.

The vowels and the consonants may be colored in order to differentiate the key groupings, with adjacent groups being differently colored. For example, all of the consonants within both of the consonant groups BCD and RST may be of a same first color which is a different color than any other of the consonant groups and the vowels. Each of the consonants within the consonant group FGHJK may be of a same second color. Each of the consonants within the consonant group LMNPQ may be of a same third color. Each of the consonants within the consonant group VWXYZ may be of a same fourth color. The first color, the second color, the third color, and the fourth color may each comprise different colors. As discussed above, a variety of colors may be used to differentiate the groupings, such as yellow, blue, red, green, tan, purple, gray, white, and the like.

In the FIG. 5 example embodiment, in Group (22) the letters B, C, and D may be arranged on the top, middle, and bottom rows, respectively. In Group (23) the letters F and G may be arranged on the top row, the letter H may be arranged on the middle row, and the letters JK may be arranged on the bottom row. In Group (24), the letters L and M may be arranged on the top row, the letters N and P may be arranged on the middle row, and the letter Q may be arranged on the bottom row. In Group (25), the letters R, S, and T may be arranged on the top, middle, and bottom rows, respectively. In Group (26), the letters V and W may be arranged on the top row, the letters X and Y may be arranged on the middle row, and the letter Z may be arranged on the bottom row.

In any of the example embodiments, the keys or the lettering on the keys may be colored. For example, the letters may be colored letters on a black background. Alternatively, the key itself (e.g., the background) may be colored with the letters appearing in black or white (or other contrasting color). In addition, the keys of each group may be one color with the lettering of each group in a contrasting color. Any combination of colored lettering and colored keys may be used, as long as adjacent groupings are differentiated by different colored keys and/or lettering.

Some of the groupings of keys may have the same color, as long as adjacent groups of keys are of a different color. For example, in one example embodiment, the vowels may be the same color as the each of the consonants within the consonant group VWXYZ.

The keyboard may comprise one of a mechanical keyboard, a computer keyboard, an electronic keyboard, a smartphone keyboard, a tablet keyboard, a touch screen keyboard, or the like.

As shown in FIG. 6, the keyboard may also comprise a dual character keyboard where the alphabetic keys comprise both an English language letter 30, and a foreign language letter, character, and/or symbol 32 (denoted by C1, C2, C3, etc.). For example, the computer keyboard can be employed in dual character keyboards that also use written symbols such Chinese, Japanese, or Arabic characters or other languages. The computer keyboard would also provide these users with a logical arrangement of the letters consistent with their learning of the English language. For example, FIG. 6 shows the arrangement of keys described above in connection with FIG. 5, modified to include the foreign language letters, characters, or symbols 32.

### Advantages

In accordance with the foregoing descriptions of the difficulty of learning the QWERTY keyboard, several advantages are provided by the embodiments of the present invention as disclosed herein, as follows: the letters of the keyboard are laid out in an ordered arrangement based on alphabetical groupings that is apparent to all readers of the English language. The groupings are further differentiated by color. This makes learning to type a more intuitive matter based on the foregoing knowledge of the typist, rather than a rote memorization of the position of each letter key through repetition. The beginning typist or a typist familiar with QWERTY keyboard will immediately recognize the logical arrangement of the letters in the embodiments of the keyboard design of the present invention. The typist will easily determine the general location and then the specific location of any letter on the keyboard, based on the colored groupings. Thereafter, the typist will progress from easily identifying individual letters, to familiarity with the location of all keys, to touch typing. The advantage of the new keyboard is that it significantly reduces the problem of the lengthy period any person must train to learn the ubiquitous QWERTY keyboard.

Accordingly, it will be seen that the invention can be applied to a variety of applications, including but not limited to, standard typewriters, electric typewriters, stand-alone electronic keyboards for use with personal computers, computers using a screen for touch entry of data, tablet computers, electronic smartphones, smart pads, point of sale devices, and any other device now existing or invented in the future that will be used to enter alphabetic data.

While the invention has been described in connection with an example embodiment, it is not intended to limit the scope of the invention to the particular form set forth herein, but on the contrary, it is intended to cover such alternatives, modifications, and equivalents as may be included within the spirit and scope of the invention as defined by the appended claims.

What is claimed is:

1. An apparatus for entering alphabetic data into a computer or other electronic or mechanical devices, comprising:
a keyboard having three rows of 10-9-7 alphabetic keys, with ten keys on a top row, nine keys on a middle row and seven keys on a bottom row, wherein:
the keys are placed in an ordered arrangement;
vowels AEIOU are grouped together;
the vowels are arranged on a left side of the keyboard;
the vowels are arranged in alphabetic order vertically across the three rows of keys with letters AE on the top row, the letters IO on the middle row, and the letter U on the bottom row;
each of the vowels has a same color;
consonants are arranged in consonant groups comprised of BCD, FGHJK, LMNPQ, RST, and VWXYZ;
the consonant groups are arranged from left to right in alphabetic group order; and
the consonants in each of the consonant groups are arranged vertically across the three rows of the keys.

2. An apparatus in accordance with claim 1, wherein:
adjacent consonant groups each have a different color; and
the consonant group BCD is adjacent to the vowels and has a different color from the color of the vowels.

3. An apparatus in accordance with claim 1, wherein:
all of the consonants within both of the consonant groups BCD and RST are of a same first color which is a different color than any other of the consonant groups and the vowels;
each of the consonants within the consonant group FGHJK are of a same second color;
each of the consonants within the consonant group LMNPQ are of a same third color;
each of the consonants within the consonant group VWXYZ are of a same fourth color; and
the first color, the second color, the third color, and the fourth color each comprise different colors.

4. An apparatus in accordance with claim 1, wherein the vowels are the same color as the each of the consonants within the consonant group VWXYZ.

5. An apparatus in accordance with claim 1, wherein at least one of the keys and the lettering on the keys is colored.

6. An apparatus in accordance with claim 1, wherein the keyboard comprises one of a mechanical keyboard, computer keyboard, an electronic keyboard, a smartphone keyboard, a tablet keyboard, a point of sale keyboard, and a touch screen keyboard.

7. An apparatus in accordance with claim 1, wherein:
the keyboard comprises a dual character keyboard; and
the alphabetic keys comprise both an English language letter and a foreign language letter, character, or symbol.

8. An apparatus in accordance with claim 1, wherein:
the letters F and G are arranged on the top row;
the letter H is arranged on the middle row; and
the letters JK are arranged on the bottom row.

9. An apparatus in accordance with claim 1, wherein:
the letters L and M are arranged on the top row;
the letters N and P are arranged on the middle row; and
the letter Q is arranged on the bottom row.

10. An apparatus in accordance with claim 1, wherein:
the letters V and W are arranged on the top row;
the letters X and Y are arranged on the middle row; and
the letter Z is arranged on the bottom row.
